(19) United States
(12) Patent Application Publication
(10) Pub. No.: US 2003/0048597 A1
(43) Pub. Date: Mar. 13, 2003

(54) Personal digital assistant with waterproof and dustproof functions

(76) Inventors: Shih-Chieh Wang, Taipei (TW); Chien-Lung Huang, Taipei (TW); Yen-Te Chiang, Taipei (TW); James Tseng, Shulin City (TW); Chu-Yang Hsu, Hsinchu (TW); Hsi-Hsing Hsu, Taoyuan (TW)

Correspondence Address: RABIN & CHAMPAGNE, PC, 1101 14TH STREET, NW, SUITE 500, WASHINGTON, DC, 20005, US

(21) Appl. No.: 10/199,056

(22) Filed: Jul. 22, 2002

(30) Foreign Application Priority Data
Sep. 7, 2001 (TW) 90215462

(51) Int. Cl. H05K 5/00

(52) U.S. Cl. 361/681

(57) ABSTRACT

A personal digital assistant with waterproof and dustproof functions including a carriage, an LCD module, a holding frame, a touch-control panel module, an elastic object and an upper cover is provided. The carriage is installed inside the PDA; the LCD module is mounted on the carriage while the holding frame is mounted on the LCD module; the touch-control panel module is mounted on the holding frame and is assembled to the LCD module. The elastic object is pasted in dots to the holding frame along the four edges of the touch-control panel; whereas the upper cover, which covers on top of the touch-control panel module, presses the elastic objects such that the touch-control panel module and the LCD module are tightly assembled together. The design of the personal digital assistant has the characteristics of easy assembly and disassembly as well as waterproof and dustproof functions.

This application incorporates by reference Taiwan application Serial No. 090215462, Filed Sep. 7, 2001.

### BACKGROUND OF THE INVENTION

1. Field of the Invention

The invention relates in general to a personal digital assistant, and more particularly to a personal digital assistant with waterproof and dustproof functions.

2. Description of the Related Art

The electronic product has gained its popularity nowadays and has been widely used as a means of diary keeping and schedule planning. OF all the portable electronic products available, PDA (Personal Digital Assistant) is the most popular one. PDA has a touch-control panel module and a LCD (Liquid Crystal Display) module, wherein the touch-control panel is used for the user to input instructions or data whereas the LCD module displays the inputs or the results of processing.

In the design of an ordinary PDA, the touch-control panel module is attached to the LCD module using adhesive tapes. However, such structural design has the following shortcomings:

1. Difficulties arise during assembly and disassembly of the PDA. When the touch-control panel module or the LCD module runs out of order and needs to be repaired or when the inside of the PDA needs to be cleaned, the adhesive tape needs to be removed during disassembly which could easily damage the two modules ending up with replacement of elements. Such a structural design is difficult to disassemble and is difficult to service and clean its elements.

2. Lacking waterproof and dustproof functions. Since the moisture and dusts in the living environment can easily enter into the inside of the PDA affecting the normal operation of the elements, the service life of the PDA will thus be shortened. Using a double-sided tape to assemble the touch-control panel module and the LCD module cannot effectively prevent moisture and dust from entering into the PDA.

### SUMMARY OF THE INVENTION

It is therefore an object of the invention to provide a personal digital assistant with waterproof and dustproof functions to extend its service life.

According to the object of the invention, a personal digital assistant with waterproof and dustproof functions is provided. The personal digital assistant includes a carriage, an LCD (Liquid Crystal Display) module, a holding frame, a touch-control panel module, an elastic object and an upper cover. The carriage is installed inside the PDA while the LCD module is installed on the carriage; and the touch-control panel module which is mounted on the holding frame is connected to the LCD module. The elastic object is pasted in dots to the holding frame along the four edges of the touch-control panel, whereas the upper cover, which covers the touch-control panel module, presses the elastic objects such that the touch-control panel module and the LCD module are tightly assembled together.

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIG. 1 illustrates a block diagram of a personal digital assistant according to a preferred embodiment of the invention; and

FIG. 2 illustrates a sectional view of the personal digital assistant in FIG. 1 according to the invention.

### DESCRIPTION OF THE PREFERRED EMBODIMENT

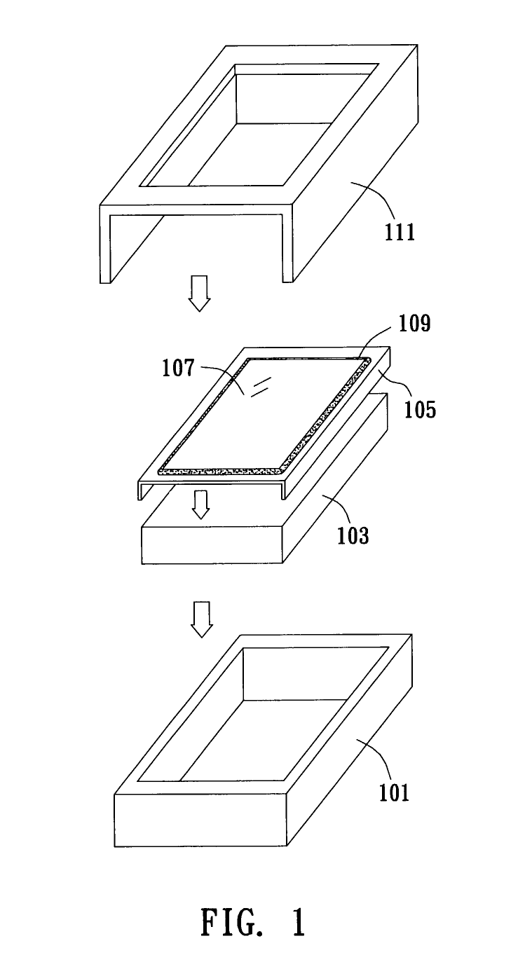

Referring first to FIG. 1, a block diagram of a personal digital assistant according to a preferred embodiment of the invention is shown. The PDA as shown in FIG. 1 includes a carriage 101, an LCD module 103, a holding frame 105, a touch-control panel module 107, an elastic object 109 and an upper cover 111. The carriage 101 is installed inside the PDA while the LCD module is mounted on the carriage.

The holding frame 105 is used to hold the touch-control panel module 107 while the touch-control panel module 107 is mounted on the LCD module 103 by means of the holding frame 105. Of which, the touch-control panel module can be connected to the holding frame 105 using, but not limited to, a double-sided tape. Furthermore, the elastic object 109 can be pasted in dots to the holding frame 105 along the four edges of the touch-control panel module 107, wherein the elastic object can be made of silicon rubber. The upper cover 111 covering the touch-control panel module 107 is connected to the carriage 101.

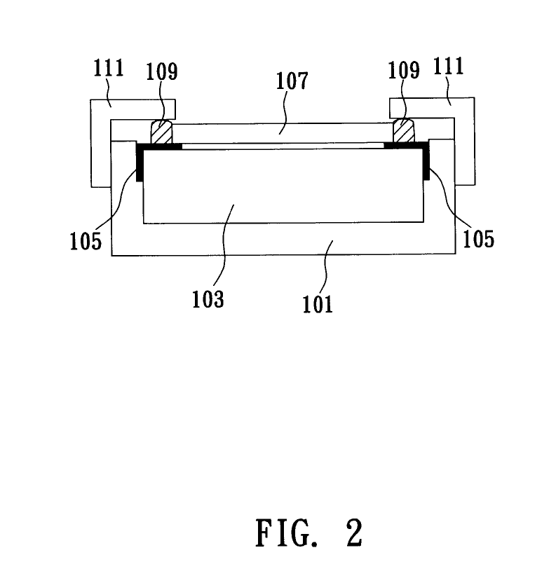

Please refer to FIG. 2, a sectional view of the personal digital assistant in FIG. 1 according to the invention at the same time. As shown in FIG. 2, having been connected to the carriage 101, the upper cover 111 will press the elastic 109 such that the touch-control panel module 107 and the LCD module 103 can be assembled more tightly. By the characteristics of the elastic object 109, the design avails the PDA according to the invention to achieve waterproof and dustproof effects.

Apart from that, the PDA according to the invention can be designed to have an ESD (Electrostatic Discharge) protecting function using the material characteristics of the elements. OF which, the carriage 101 can be made of electroplated plastics serving as a grounding for the PDA. The holding frame 105 can be a metallic frame while the elastic object 109 can be a conductive elastic object, e.g. a conductive silicon rubber, such that the elastic object 109 can immediately channel overloaded electric charges to the carriage 101 via the holding frame 105 preventing the semiconductor elements inside from electrostatic discharge damages when the PDA is touched by some objects in the environment carrying high electric charge, e.g. a human's finger.

The personal digital assistant disclosed in the above preferred embodiment according to the invention has the following advantages:

It is both waterproof and dustproof. By means of the structural design of an elastic object, the invention prevents moisture and dust from entering into the inside of the personal digital assistant such that its service life can be extended.

It has an ESD protecting function. By means of the structural design of a conductive elastic object, the invention channels overloaded charges via grounding to protect the elements inside the personal digital assistant from being damaged by electrostatic discharges.

Its easy assembly and disassembly makes maintenance and cleaning convenient. The touch-control panel module of the personal digital assistant according to the invention is mounted onto the LCD module via a holding frame. When the personal digital assistant needs to be serviced or cleaned, the technician only needs to lift the holding frame to separate the touch-control panel module and the LCD module apart in order to clean or service the elements or replace the damaged module. Therefore, the structural design of the invention is of easy assembly and disassembly and therefore makes its maintenance and cleaning convenient.

While the invention has been described by way of example and in terms of the preferred embodiment, it is to be understood that the invention is not limited to the disclosed embodiment. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A personal digital assistant (PDA), comprising:
a liquid crystal display (LCD) module installed in the personal digital assistant;
a holding frame installed on the LCD module;
a touch-control panel module mounted on the holding frame to be assembled with the LCD module;
an elastic object pasted in dots to the holding frame along the four edges of the touch-control panel; and
an upper cover, which covers on top of the touch-control panel module;
wherein the upper cover presses the elastic object, and by means of such elasticity, forcing the touch-control panel module and the LCD module to be tightly assembled.

2. A personal digital assistant according to claim 1, wherein the elastic object is a silicon rubber.

3. A personal digital assistant according to claim 1, wherein the personal digital assistant further comprises a carriage, which is used to carry the LCD module and is connected to the upper cover.

4. A personal digital assistant according to claim 3, wherein the carriage is electroplated serving as a grounding for the personal digital assistant.

5. A personal digital assistant according to claim 1, wherein the elastic object is a conductive silicon rubber.

6. A personal digital assistant according to claim 1, wherein the touch-control panel module is connected to the holding frame using an adhesive tape.
